(19) United States
(12) Patent Application Publication
(10) Pub. No.: US 2026/0052990 A1
(43) Pub. Date: Feb. 19, 2026

(54) SEMICONDUCTOR APPARATUS AND SEMICONDUCTOR SYSTEM INCLUDING THE SAME

(71) Applicant: SAMSUNG ELECTRONICS CO., LTD., Suwon-si (KR)

(72) Inventor: Sungeun JO, Suwon-si (KR)

(73) Assignee: SAMSUNG ELECTRONICS CO., LTD., Suwon-si (KR)

(21) Appl. No.: 19/022,382

(22) Filed: Jan. 15, 2025

(30) Foreign Application Priority Data
Aug. 16, 2024 (KR) 10-2024-0109518

(51) Int. Cl. H01L 23/427; G06F 1/20; H01L 25/07

(52) U.S. Cl. CPC H01L 23/427; G06F 1/20; H01L 25/072

(57) ABSTRACT

A semiconductor apparatus includes a semiconductor substrate including an active area that is divided into a plurality of sections in which a plurality of semiconductor devices are provided, and a cooling device including a vapor chamber configured to disperse heat generated by the plurality of sections through a phase change in a fluid flowing inside the vapor chamber, and a plurality of heat sinks configured to respectively cool corresponding sections of the plurality of sections through a coolant flowing inside the plurality of heat sinks.

### CROSS-REFERENCE TO RELATED APPLICATION

This application claims priority from Korean Patent Application No. 10-2024-0109518, filed on Aug. 16, 2024, in the Korean Intellectual Property Office, the disclosure of which is incorporated by reference herein in its entirety.

### BACKGROUND

### 1. Field

Methods and apparatuses consistent with embodiments relate to a semiconductor apparatus and a semiconductor system including the semiconductor apparatus.

### 2. Description of the Related Art

With the advancement of high-performance electronic devices, technologies for packaging a plurality of semiconductor devices placed within electronic devices are being developed. For example, there is an increasing need for technologies that efficiently manage the heat generated by a plurality of semiconductor devices.

### SUMMARY

One or more embodiments may address at least the problems and/or disadvantages described above, and other disadvantages not described above. Also, the embodiments are not required to overcome and may not overcome any of the problems and disadvantages described above.

According to an aspect of the disclosure, there is provided a semiconductor apparatus including: a semiconductor substrate including an active area that is divided into a plurality of sections in which a plurality of semiconductor devices are provided; and a cooling device including: a vapor chamber configured to disperse heat generated by the plurality of sections through a phase change in a fluid flowing inside the vapor chamber; and a plurality of heat sinks configured to respectively cool corresponding sections of the plurality of sections through a coolant flowing inside the plurality of heat sinks.

The vapor chamber may be provided on the semiconductor substrate, and the plurality of heat sinks may be provided on the vapor chamber.

The vapor chamber may be provided on a first side of the semiconductor substrate, and the plurality of heat sinks may be provided on a second side of the semiconductor substrate.

Each of the plurality of heat sinks may include: a first base; a second base; and a channel provided between the first base and the second base, the channel configured to enable the coolant to flow.

The channel may include a plurality of first passages extending in a first direction and provided side by side in a second direction substantially perpendicular to the first direction; and a plurality of second passages configured to connect adjacent first passages, among the plurality of second passages, and a width of each of the plurality of first passages is substantially same as a distance between the adjacent first passages.

Each of the plurality of heat sinks may be formed in a polygonal shape having a plurality of sides, each of the plurality of heat sinks may include: an inlet configured to introduce the coolant into the channel, and an outlet configured to discharge the coolant from the channel, and the inlet and the outlet of at least one of the plurality of heat sinks are positioned on a same side of the at least one of the plurality of heat sinks.

Each of the plurality of heat sinks may be formed in a polygonal shape having a plurality of sides, each of the plurality of heat sinks may include: an inlet configured to introduce the coolant into the channel, and an outlet configured to discharge the coolant from the channel, and the inlet and the outlet of at least one of the plurality of heat sinks are positioned on different sides of the at least one of the plurality of heat sinks.

The cooling device may further include a thermal interface material (TIM) provided between the semiconductor substrate and the vapor chamber.

The cooling device may further include a thermal interface material (TIM) provided between the vapor chamber and the plurality of heat sinks.

The cooling device may further include an inner wall provided between adjacent sections, among the plurality of sections.

The cooling device may further include an outer wall provided along a perimeter of the active area.

At least one of the inner wall or the outer wall may include at least one of stainless steel, aluminum, or a combination of stainless steel and aluminum.

At least two of the plurality of sections may have substantially a same size.

At least two of the plurality of sections may have different sizes.

The semiconductor substrate may have a scale of a wafer level system.

According to another aspect of the disclosure, there is provided a semiconductor apparatus including: a semiconductor substrate including an active area that is divided into a plurality of sections in which a plurality of semiconductor devices are provided; and a cooling device including: a vapor chamber configured to disperse heat generated by the plurality of sections through a phase change in a fluid flowing inside the vapor chamber; and a plurality of heat sinks configured to respectively cool corresponding sections among the plurality of sections through a coolant flowing inside the plurality of heat sinks, wherein an area of the active area is at least about 22,500 square millimeters (mm²).

At least some of the plurality of semiconductor devices may be connected to one another to form at least one chiplet.

The at least one chiplet may include an active element, a memory element, or a combination of an active element and a memory element.

According to another aspect of the disclosure, there is provided a semiconductor system including: a semiconductor apparatus including: a semiconductor substrate at a wafer level system scale, the semiconductor substrate including an active area that is divided into a plurality of sections; a plurality of semiconductor devices provided in the active area of the semiconductor substrate, and a cooling device configured to cool the active area of the semiconductor substrate; a coolant supply device configured to supply a coolant to the cooling device; a sensor device configured to obtain temperature information for each of the plurality of sections; and a control device configured to: receive the temperature information from the sensor device; and control the coolant supply device to supply of the coolant to independently adjust a temperature of each of the plurality of sections based on the temperature information obtained for each of the plurality of sections.

The cooling device may include a vapor chamber configured to disperse heat generated by the plurality of sections through a phase change in a fluid flowing inside the vapor chamber; and a plurality of heat sinks configured to respectively cool corresponding sections among the plurality of sections through a coolant flowing inside the plurality of heat sinks, and the coolant supply device is connected to the plurality of heat sinks and configured to supply the coolant to the plurality of heat sinks.

### BRIEF DESCRIPTION OF DRAWINGS

The accompanying drawings illustrate example embodiments of the disclosure and are provided together with the detailed description for better understanding of the technical idea of the disclosure. Therefore, the disclosure should not be construed as being limited to the embodiments set forth in the drawings.

FIG. 1 is a perspective view of a semiconductor apparatus according to an embodiment.

FIG. 2A is a plan view of a semiconductor apparatus, according to an embodiment.

FIG. 2B is a cross-sectional view taken along line I-I of FIG. 2A.

FIG. 2C is a diagram illustrating the interior of an enlarged area A of FIG. 2A.

FIG. 2D is a diagram illustrating the interior of a heat sink, according to an embodiment.

FIG. 3 is a diagram illustrating a semiconductor substrate and an active area formed on the semiconductor substrate, according to an embodiment.

FIG. 4 is a plan view illustrating sizes of a plurality of sections formed in a semiconductor apparatus, according to an embodiment.

FIG. 5 is a plan view illustrating a number of sections formed in a semiconductor apparatus, according to an embodiment.

FIG. 6 is a cross-sectional view of a semiconductor apparatus in which a vapor chamber is provided between a plurality of semiconductor substrates, according to an embodiment.

FIG. 7 is a diagram schematically illustrating a semiconductor system according to an embodiment.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not intended to be limiting. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one component from another component, and the nature, the sequences, or the orders of the components are not limited by the terms. When one component is described as being “connected”, “coupled”, or “attached” to another component, it should be understood that one component may be connected or attached directly to another component, and an intervening component may also be “connected”, “coupled”, or “attached”to the components.

In the expressions used herein, the term “top” may refer to the +Z direction based on the direction illustrated in the drawings, and the term “bottom” may refer to the −Z direction opposite to the top. However, this is for ease of description, and the terms “top” and “bottom” may refer to a relative arrangement relationship. For example, when components illustrated in a drawing are viewed in the opposite direction, the term “top” used herein may refer to the −Z direction with respect to the direction illustrated in the drawings, and the term “bottom”may refer to the +Z direction.

As used herein, the terms “substantially”, “approximately”, “generally”, and “about” in reference to a given parameter, property, or condition may include a degree that one of ordinary skill in the art would understand that the given parameter, property, or condition is met with a small degree of variance, such as within acceptable manufacturing tolerances. For example, a particular parameter that is substantially satisfied may be a range including any one of +/−0.1%, +/−0.5%, +/−1%, +/−3%, +/−5%, +/−7%, +/−10%, +/−15%, and +/−20%, based on the literally same 0%.

The same name may be used to describe an element included in the embodiments described above and an element having a common function. Unless stated otherwise, the description of an embodiment may be applicable to other embodiments, and a repeated description related thereto is omitted.

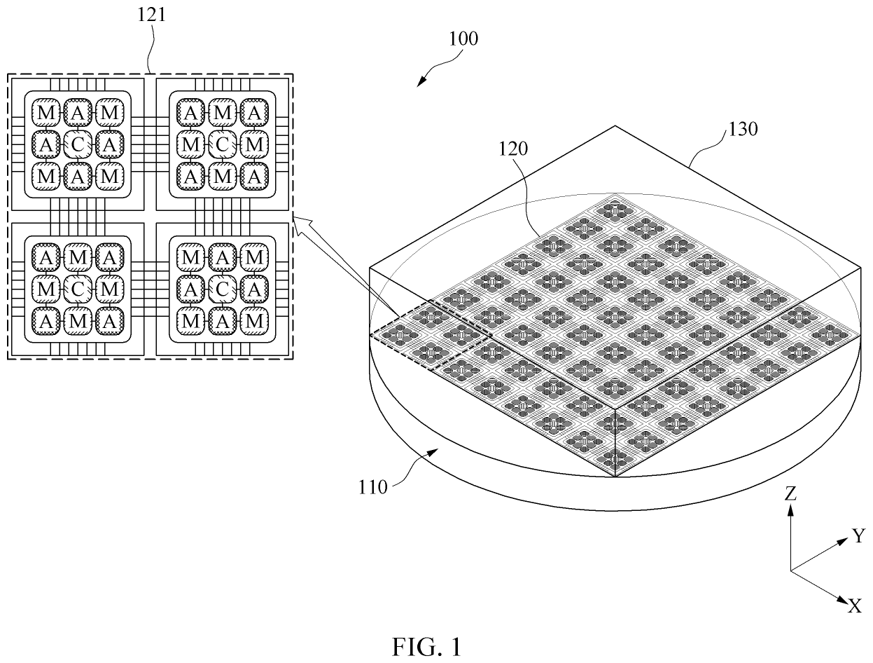

FIG. 1 is a perspective view of a semiconductor apparatus 100 according to an embodiment.

Referring to FIG. 1, according to an embodiment, the semiconductor apparatus 100 may include a semiconductor substrate 110, a plurality of semiconductor devices 120 mounted on the semiconductor substrate 110, and a cooling device 130 provided on the semiconductor substrate 110.

In an embodiment, the semiconductor substrate 110 may support the plurality of semiconductor devices 120. The semiconductor substrate 110 may provide electrical connections between the plurality of semiconductor devices 120. The semiconductor substrate 110 may transfer heat generated by the plurality of semiconductor devices 120 to other components. The semiconductor substrate 110 may be formed of various materials. For example, the material of the semiconductor substrate 110 may include, but is not limited to, at least one of silicon, glass, gallium nitride (GaN), ceramic or plastic, or a combination thereof. However, this is only an example, and the material of the semiconductor substrate 110 is not limited to those above and may include various materials capable of supporting the plurality of semiconductor devices 120. Additionally, the shape of a semiconductor substrate may be various shapes depending on the manufacturing method and the like. For example, the shape of a semiconductor substrate may include, but is not limited to, a circular or polygonal shape.

In an embodiment, the plurality of semiconductor devices 120 may be mounted on the semiconductor substrate 110. The plurality of semiconductor devices 120 and the semiconductor substrate 110 may form a wafer level system in which reticles are connected to each other. Each reticle may include at least one of a processor, a memory (M), or a combination thereof. A processor or a memory (M) included in a plurality of reticles may be the same or different for each reticle. The processor may include, but is not limited to, a central processing unit (CPU), a graphics processing unit (GPU), an artificial intelligence (AI) accelerator (A), etc. The memory may include a volatile memory or a non-volatile memory. The AI accelerator (A) is a specialized semiconductor device designed to accelerate artificial intelligence computations, including deep learning, machine learning, and data analysis. The CPU (C) is a central processing unit responsible for executing instructions, managing tasks, and coordinating system operations. The memory (M) is a component that stores data and provides fast access to data required by the CPU (C) and AI Accelerator (A), optimizing the system's data processing speed. The scale of the wafer-level system described herein is based on a wafer with a diameter of 300 mm (12 inches), which includes a structure capable of integrating up to 100 chiplets on a single wafer. The cooling device is designed to accommodate the physical dimensions of such wafers and the density of the chiplets, providing uniform thermal management across the entire wafer and preventing deformation.

The plurality of semiconductor devices 120 mounted on the semiconductor substrate 110 may be electrically connected to one another. Each of the plurality of semiconductor devices 120 may perform the same function or different functions. According to an embodiment, at least some of the plurality of semiconductor devices 120 may be connected to one another to form at least one chiplet 121. For example, referring to FIG. 1, one chiplet 121 may be a system (a 4-reticle scale system) formed by four reticles electrically connected to one another. However, this is only an example, and the scale of the chiplet 121 is not limited to the case in which four reticles are connected to one another and may include various scales. For example, the number of reticles electrically connected to one another may be different than four. The chiplet 121 may include an active element, a memory element, or a combination of an active element and a memory element. The active element may include, but is not limited to, a transistor, a diode, an operational amplifier, a silicon controlled rectifier (SCR), or a metal-oxide-semiconductor field-effect transistor (MOSFET) etc. The memory element may include a volatile memory element or a non-volatile memory element. The plurality of semiconductor devices 120 may be provided on the semiconductor substrate 110 to form an active area. The active area may be divided into sections by at least one chiplet 121. When viewed from the top of the semiconductor substrate 110 (e.g., in the +Z-axis direction of FIG. 1), the active area may be formed in a quadrangular shape. However, this is only an example, and the shape of the active area may be various shapes (e.g., a circular or polygonal shape) depending on the arrangement of the semiconductor devices 120.

In an embodiment, the cooling device 130 may be provided on the semiconductor substrate 110. For example, the cooling device 130 may cool the semiconductor substrate 110. However, the disclosure is not limited thereto, and as such, according to another embodiment, the cooling device 130 may be referred to a temperature controlling device configured to control a temperature of the semiconductor substrate 110 and/or the plurality of semiconductor devices 120. The cooling device 130 may cool the semiconductor substrate 110 so that the temperature of the plurality of semiconductor devices 120 that generates heat remains within a reference range or the cooling device 130 may receive heat from the semiconductor substrate 110 and externally discharge the heat. For example, the plurality of semiconductor devices 120 may be mounted on the semiconductor substrate 110, and the heat generated by the plurality of semiconductor devices 120 may be transferred to the cooling device 130 through the semiconductor substrate 110. The cooling device 130 may move the heat from the semiconductor substrate 110 to the outside through thermal conduction. For example, at least some components of the cooling device 130 may include a thermally conductive material. The cooling device 130 may evenly disperse the heat received through the fluid flowing in the cooling device 130. For example, the fluid flowing inside the cooling device 130 may repeat evaporation and condensation through a phase change, and heat transferred through repeated phase changes may be substantially evenly distributed in the cooling device 130.

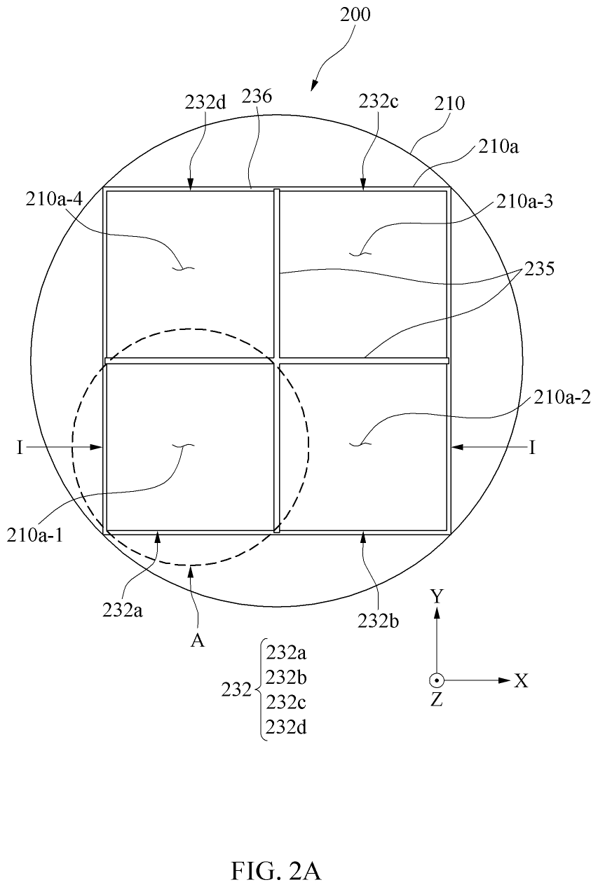

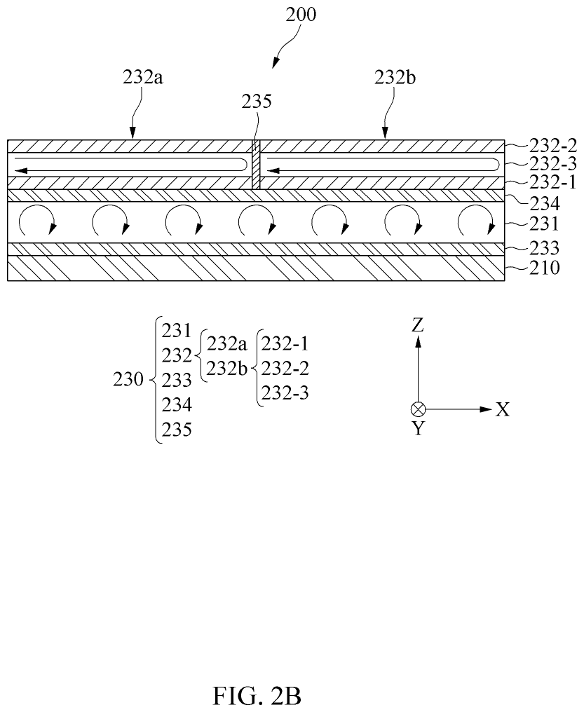

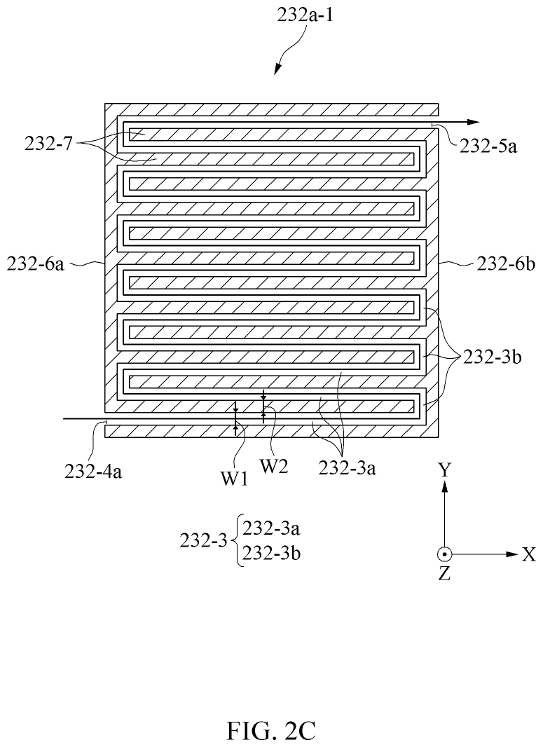

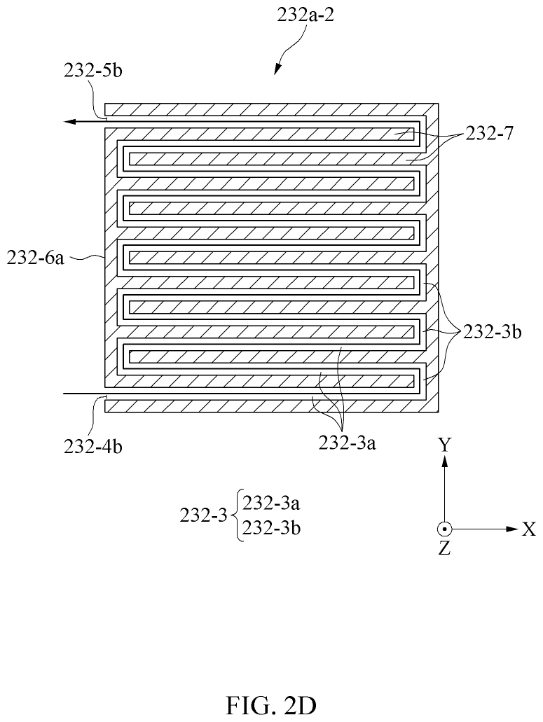

FIG. 2A is a plan view of a semiconductor apparatus 200 according to an embodiment, FIG. 2B is a cross-sectional view taken along line I-I of FIG. 2A, FIG. 2C is a diagram illustrating the interior of an enlarged area A of FIG. 2A, and FIG. 2D is a diagram illustrating the interior of a heat sink 232, according to an embodiment.

Referring to FIGS. 2A to 2D, the semiconductor apparatus 200 (e.g., the semiconductor apparatus 100 of FIG. 1) may include a semiconductor substrate 210 (e.g., the semiconductor substrate 110 of FIG. 1), a plurality of semiconductor devices (e.g., the plurality of semiconductor devices 120 of FIG. 1) mounted on the semiconductor substrate 210, and a cooling device 230 (e.g., the cooling device 130 of FIG. 1) configured to cool the semiconductor substrate 210.

In an embodiment, the plurality of semiconductor devices may be mounted on the semiconductor substrate 210. The plurality of semiconductor devices mounted on the semiconductor substrate 210 may form an active area 210a. At least some of the plurality of semiconductor devices may be connected to one another to form a chiplet (e.g., the chiplet 121 of FIG. 1). According to an embodiment, a plurality of chiplets may be formed by the plurality of semiconductor devices, and at least one of the plurality of chiplets may form at least one section (e.g., 210a-1, 210a-2, 210a-3, and 210a-4). According to an embodiment, a plurality of sections 210a-1, 210a-2, 210a-3, and 210a-4 formed in the active area 210a may have substantially the same size. However, the disclosure is not limited thereto.

Referring to FIG. 2A, according to an embodiment, the cooling device 230 may include a vapor chamber 231 provided on the semiconductor substrate 210, a plurality of heat sinks 232 provided in the active area 210a of the semiconductor substrate 210, a first thermal interface material (TIM) 233 provided between the semiconductor substrate 210 and the vapor chamber 231, a second TIM 234 provided between the vapor chamber 231 and the plurality of heat sinks 232, an inner wall 235 provided inside the active area 210a, and an outer wall 236 provided along the outer perimeter of the active area 210a. For example, the plurality of heat sinks 232 may include a first heat sinks 232a, a second heat sinks 232b, a third heat sinks 232c, and a fourth heat sinks 232c.

In an embodiment, the vapor chamber 231 may be provided on the semiconductor substrate 210. For example, the vapor chamber 231 may be provided on the top (e.g., in the +Z-axis direction of FIG. 2B) of the semiconductor substrate 210. A fluid that undergoes a phase change within a reference temperature range may flow inside the vapor chamber 231. For example, the reference temperature range may be a predetermined range. The fluid flowing inside the vapor chamber 231 may undergo a phase change between evaporation and condensation when heat is transferred from the semiconductor substrate 210 to the vapor chamber 231. In the process in which the phase of the fluid repeatedly changes, the heat transferred from the semiconductor substrate 210 to the vapor chamber 231 may be substantially evenly distributed along the inner area of the vapor chamber 231. The vapor chamber 231 is illustrated as being provided on the top of the semiconductor substrate 210. However, this is only an example, and the vapor chamber 231 may also be provided on the bottom (e.g., in the −Z-axis direction of FIG. 2B) of the semiconductor substrate 210. According to an embodiment, the vapor chamber 231 may be provided directly on the semiconductor substrate 210. However, the disclosure is not limited thereto, and as such, according to another embodiment, the vapor chamber 231 may be provided on the semiconductor substrate 210 with one or more components interposed between the semiconductor substrate 210 and the vapor chamber 231.

In an embodiment, the plurality of heat sinks 232 may cool a semiconductor device by absorbing or externally discharging heat generated by the plurality of semiconductor devices mounted on the semiconductor substrate 210. For example, a channel through which a coolant flows may be formed inside the plurality of heat sinks 232. The plurality of heat sinks 232 may be provided on the top or bottom of the semiconductor substrate 210 together with the vapor chamber 231 with respect to the semiconductor substrate 210 or may be provided in the opposite side to the vapor chamber 231 with respect to the semiconductor substrate 210. Referring to FIG. 2B, the plurality of heat sinks 232 may be provided on the top of the vapor chamber 231. However, this is only an example, and as such, in an example case in which, the vapor chamber 231 according to an embodiment is provided on the top of the semiconductor substrate 210, the plurality of heat sinks 232 may be provided on the bottom (e.g., in the −Z-axis direction of FIG. 2B) of the semiconductor substrate 210.

The plurality of heat sinks 232 may be provided to substantially and respectively overlap the plurality of sections 210a-1, 210a-2, 210a-3, and 210a-4 formed in the active area 210a of the semiconductor substrate 210, when viewed from the top (e.g., in the +Z-axis direction of FIG. 2A) of the semiconductor substrate 210. For example, each of the plurality of heat sinks 232a, 232b, 232c, and 232d may be respectively provided in the plurality of sections 210a-1, 210a-2, 210a-3, and 210a-4 of the active area 210a. The plurality of heat sinks 232a, 232b, 232c, and 232d may be separated from one another and provided in the plurality of sections 210a-1, 210a-2, 210a-3, and 210a-4, respectively, at least two of the plurality of heat sinks 232 may be connected to one another to form one heat sink 232, and the at least two heat sinks 232 may be provided to overlap each of the plurality of sections 210a-1, 210a-2, 210a-3, and 210a-4. The plurality of heat sinks 232a, 232b, 232c, and 232d may be provided to overlap the plurality of sections 210a-1, 210a-2, 210a-3, and 210a-4 formed in the active area 210a, respectively, and each of the plurality of overlapping sections 210a-1, 210a-2, 210a-3, and 210a-4 may be cooled. Each of the plurality of heat sinks 232a, 232b, 232c, and 232d may independently cool a respective one of the plurality of sections 210a-1, 210a-2, 210a-3, and 210a-4 individually. For example, the first heat sink 232a may cool the first section 210a-1, the second heat sink 232b may cool the second section 210a-2, the third heat sink 232c may cool the third section 210a-3, and the fourth heat sink 232d may cool the second section 210a-4. The plurality of sections 210a-1, 210a-2, 210a-3, and 210a-4 independently cooled by a respective one of the plurality of heat sinks 232a, 232b, 232c, and 232d may be cooled to be in substantially the same temperature range, or at least two of the sections 210a-1, 210a-2, 210a-3, and 210a-4 may be cooled to be in different temperature ranges. The cooling device 230 may control the temperature of the entire active area 210a on the semiconductor substrate 210 as the plurality of heat sinks 232a, 232b, 232c, and 232d cool the plurality of sections 210a-1, 210a-2, 210a-3, and 210a-4, respectively. Accordingly, the cooling power required in the process of cooling the temperature of the entire active area 210a may be reduced. According to an embodiment, the cooling power may be calculated as a product of the difference between the coolant pressure at inlets 232-4a (FIG. 2C) and 232-4b (FIG. 2D) and the coolant pressure at outlets 232-5a (FIG. 2C) and 232-5b (FIG. 2D) of each of the heat sinks 232a, 232b, 232c, and 232d and the coolant flow rate, and the cooling efficiency may be increased.

In an embodiment, each of the plurality of heat sinks 232a, 232b, 232c, and 232d may include a lower base 232-1, an upper base 232-2, and a cooling channel 232-3. The lower base 232-1 and the upper base 232-2 may form the lower exterior and the upper exterior of the heat sink 232, respectively. The material of at least one of the lower base 232-1 and the upper base 232-2 may be formed of at least one of copper, aluminum, or a combination thereof. However, the disclosure is not limited thereto, and as such, according to another embodiment, the lower base 232-1 and the upper base 232-2 may be formed of another material.

In an embodiment, the cooling channel 232-3 may be formed between the lower base 232-1 and the upper base 232-2. For example, the cooling channel 232-3 may be formed by the lower base 232-1 and the upper base 232-2 positioned to face the lower base 232-1. In an embodiment, the cooling channel 232-3 may include a plurality of horizontal passages 232-3a and a plurality of vertical passages 232-3b. The plurality of horizontal passages 232-3a of the cooling channel 232-3 may be formed to extend in a horizontal direction (e.g., the X-axis direction of FIG. 2C) when the cooling device 230 is viewed from above. The plurality of horizontal passages 232-3a may be formed in parallel in a vertical direction (e.g., the Y-axis direction in FIG. 2C) substantially perpendicular to the horizontal direction. The plurality of horizontal passages 232-3a formed side by side in the vertical direction may be concatenated by the plurality of vertical passages 232-3b. For example, the plurality of vertical passages 232-3b may connect adjacent horizontal passages among the plurality of horizontal passages 232-3a. The cooling channel 232-3 may be formed in a meander type by the plurality of horizontal passages 232-3a and the plurality of vertical passages 232-3b. The plurality of vertical passages 232-3b may connect horizontal passages 232-3a adjacent to each other among the plurality of horizontal passages 232-3a in the vertical direction. According to an embodiment, each of the plurality of heat sinks 232 may include passage walls 232-7 provided between the horizontal passages 232-3a. According to an embodiment, a width W1 (e.g., the length in the Y-axis direction of FIG. 2C) of each of the plurality of horizontal passages 232-3a may be substantially the same as a distance W2 between the horizontal passages 232-3a adjacent to each other. For example, the width W1 of each of the plurality of horizontal passages 232-3a may be substantially the same as a distance W2 of the passage walls 232-7.

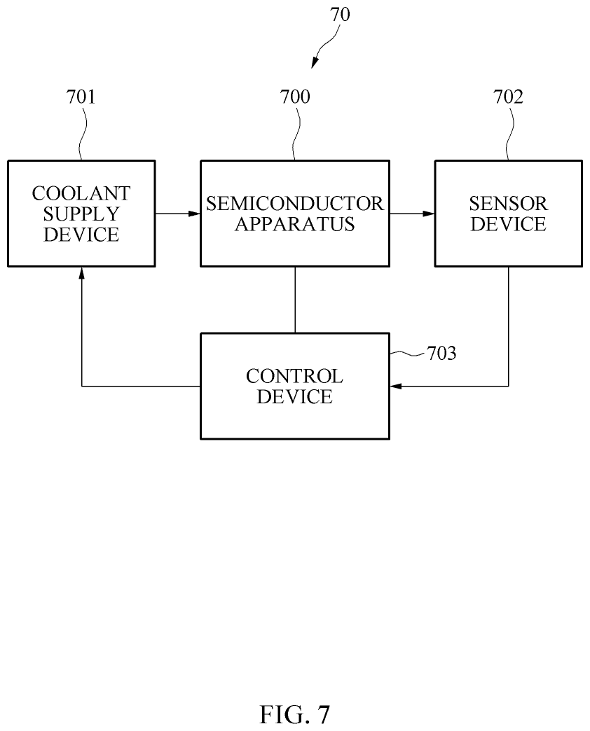

According to an embodiment, the inlets 232-4a and 232-4b for introducing a coolant and the outlets 232-5a and 232-5b for discharging a coolant to the outside may be formed in a channel of each of the plurality of heat sinks 232a, 232b, 232c, and 232d. In an embodiment, the inlets 232-4a and 232-4b may be configured to allow a coolant to flow into the channel from the outside (e.g., a coolant supply device 701 of FIG. 7). The outlets 232-5a and 232-5b may be configured to discharge the coolant from the channel to the outside. The coolant flowing inside each of the plurality of heat sinks 232a, 232b, 232c, and 232d may be provided in liquid form (e.g., water). According to an embodiment, a coolant may be set to be about 45° C. or less in the heat sink 232. In another embodiment, the coolant may be set to be about 40° C. or less. In another embodiment, the coolant may be set to be about 35° C. or less. In another embodiment, the coolant may be set to be about 32° C. or less in the heat sink 232.

According to an embodiment, each of the plurality of heat sinks 232a-1 and 232a-2 may be formed in a polygonal shape (e.g., a quadrangular shape) having a plurality of sides 232-6a and 232-6b when viewed from the top of the cooling device 230. Referring to FIG. 2C, the inlet 232-4a and the outlet 232-5a may be positioned on different sides 232-6a and 232-6b among the sides 232-6a and 232-6b of the heat sink 232a-1. Referring to FIG. 2D, the inlet 232-4b and the outlet 232-5b may be positioned on the same side 232-6a of the heat sink 232a-2. However, the positions of the inlets 232-4a and 232-4b and the outlets 232-5a and 232-5b illustrated in FIGS. 2C and 2D are only examples and are not limited thereto. The positions of the inlets 232-4a and 232-4b and the outlets 232-5a and 232-5b may be various positions (e.g., on the side in the Z-axis direction of the heat sink 232).

In an embodiment, a thermal interface material (TIM) may be provided between two components to perform a heat transfer function. The TIM may be a thermally conductive material. The TIM may include a first TIM 233 and a second TIM 234. The first TIM 233 may be provided between the semiconductor substrate 210 and the vapor chamber 231. The first TIM 233 may transfer heat generated from the semiconductor substrate 210 to the vapor chamber 231. The second TIM 234 may be provided between the vapor chamber 231 and the plurality of heat sinks 232. The second TIM 234 may transfer heat dispersed inside the vapor chamber 231 through a fluid flowing inside the vapor chamber 231 to the plurality of heat sinks 232 provided on the vapor chamber 231. In an embodiment, the first TIM 233 and the second TIM 234 may have a thermal conductivity of about 6 watts per meter-Kelvin (W/mK) to about 10 milliwatts per meter per Kelvin (mW/mK). According to another embodiment, the first TIM 233 and the second TIM 234 may have a thermal conductivity of about 7 W/mK to about 9 mW/mK. In yet another embodiment, the first TIM 233 and the second TIM 234 may have a thermal conductivity of about 8 W/mK. In an embodiment, the thickness (e.g., the length in the Z-axis direction of FIG. 2B) of the first TIM 233 and the second TIM 234 may be from about 30 micrometers (μm) to about 70μm. In another embodiment, the thickness of the first TIM 233 and the second TIM 234 may be from about 40μm to about 60μm. In yet another embodiment, the thickness of the first TIM 233 and the second TIM 234 may be about 50μm.

According to an embodiment, an inner wall 235 of the cooling device 230 may be provided between sections 210a-1, 210a-2, 210a-3, and 210a-4 adjacent to one another among the plurality of sections 210a-1, 210a-2, 210a-3, and 210a-4 formed in the active area 210a of the semiconductor substrate 210. The inner wall 235 may form the boundaries between the plurality of sections 210a-1, 210a-2, 210a-3, and 210a-4. The inner wall 235 may form the boundary between the plurality of heat sinks 232. For example, the plurality of heat sinks 232 may be provided to respectively overlap the plurality of sections 210a-1, 210a-2, 210a-3, and 210a-4 of the active area 210a, and the inner wall 235 may be provided between the heat sinks 232 adjacent to one another among the plurality of heat sinks 232 and between the sections 210a-1, 210a-2, 210a-3, and 210a-4 adjacent to one another among the plurality of sections 210a-1, 210a-2, 210a-3, and 210a-4, thereby forming the boundaries between the heat sinks 232 and the boundaries between the plurality of sections 210a-1, 210a-2, 210a-3, and 210a-4. In an example case in which the number of sections 210a-1, 210a-2, 210a-3, and 210a-4 formed in the active area 210a is four as shown in FIG. 2A, the inner wall 235 may be provided in a cross shape. The outer wall 236 of the cooling device 230 according to an embodiment may be provided along the perimeter of the active area 210a. According to an embodiment, the inner wall 235 and the outer wall 236 of the cooling device 230 may be respectively provided at the inner boundary and the outer boundary of the active area 210a to prevent or reduce substrate warpage that may occur due to other components provided on the semiconductor substrate 210. In an example case in which the inner wall 235 in a cross shape is provided between the plurality of sections 210a-1, 210a-2, 210a-3, and 210a-4, the degree of substrate warpage may be reduced by about 25% or more. In another embodiment, the degree of substrate warpage may be reduced by about 40% or more. In yet another embodiment, the degree of substrate warpage may be reduced by about 50% or more. At least one of the inner wall 235 or the outer wall 236 may be formed of stainless steel, aluminum, or a combination thereof. However, the disclosure is not limited thereto, and as such, the inner wall 235 or the outer wall 235 may be formed of another material.

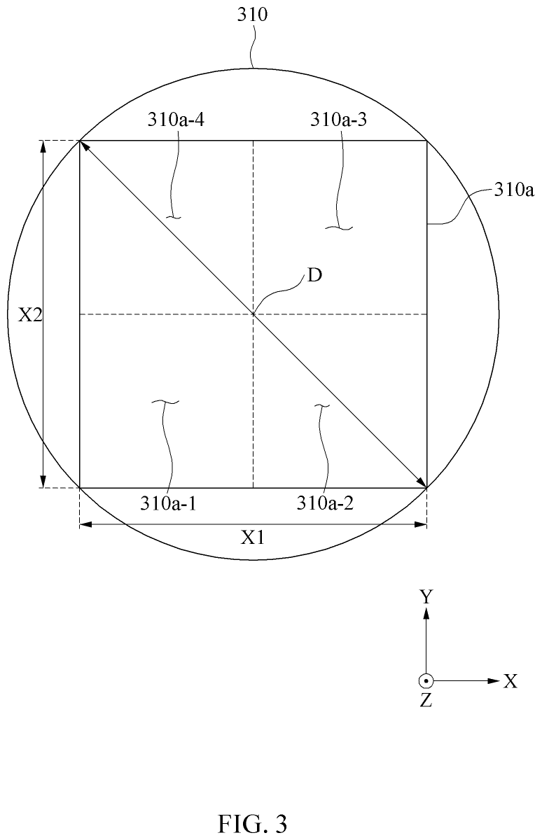

FIG. 3 is a diagram illustrating a semiconductor substrate 310 and an active area 310a formed on the semiconductor substrate 310, according to an embodiment.

Referring to FIG. 3, the semiconductor substrate 310 (e.g., the semiconductor substrate 210 of FIG. 2A) may include the active area 310a (e.g., the active area 210a of FIG. 2A) formed by a plurality of semiconductor devices. The active area 310a may be divided into a plurality of sections 310a-1, 310a-2, 310a-3, and 310a-4 (e.g., the plurality of sections 210a-1, 210a-2, 210a-3, and 210a-4 of FIG. 2A). According to an embodiment, a diameter D of the semiconductor substrate 310 may be at least about 300 mm. The active area 310a formed on the semiconductor substrate 310 may have a length X1 in a first direction (e.g., the X-axis direction of FIG. 3) and a length X2 in a second direction (e.g., the Y-axis direction of FIG. 3) when viewed from the top of the semiconductor substrate 310 (e.g., in the +Z-axis direction of FIG. 3). In an embodiment, the area of the active area 310a may be a product of the length X1 in the first direction and the length X2 in the second direction. The length X1 in the first direction and the length X2 in the second direction of the active area 310a may each be at least about 150 millimeters (mm) and at most about 215 mm. The length X1 in the first direction of the active area 310a may be substantially the same as or different from the length X2 in the second direction of the active area 310a. The area of the active area 310a may be at least about 22,500 mm² and at most about 46,225 mm². In an example case in which the diameter D of the semiconductor substrate 310 is at least about 300 mm, the area of the active area 310a formed on the semiconductor substrate 310 is about 22,500 mm² to about 46,225 mm², and at least some of a plurality of semiconductor devices (e.g., the plurality of semiconductor devices 120 of FIG. 1) provided on the active area 310a are connected to one another to form a chiplet (e.g., the chiplet 121 of FIG. 1). Moreover, the semiconductor substrate 310 and the plurality of semiconductor devices mounted on the semiconductor substrate 310 may be formed at the scale of a wafer level system in which a plurality of semiconductor devices (dies) and related circuits are implemented on a single substrate. According to an embodiment, a cooling device may be a device configured to cool a substrate and a plurality of semiconductor devices formed at the scale of a wafer level system. However, the size of the substrate and the area range of the active area 310a as described above are only examples, and the size of the substrate and the area range of the active area 310a may be formed in various ranges.

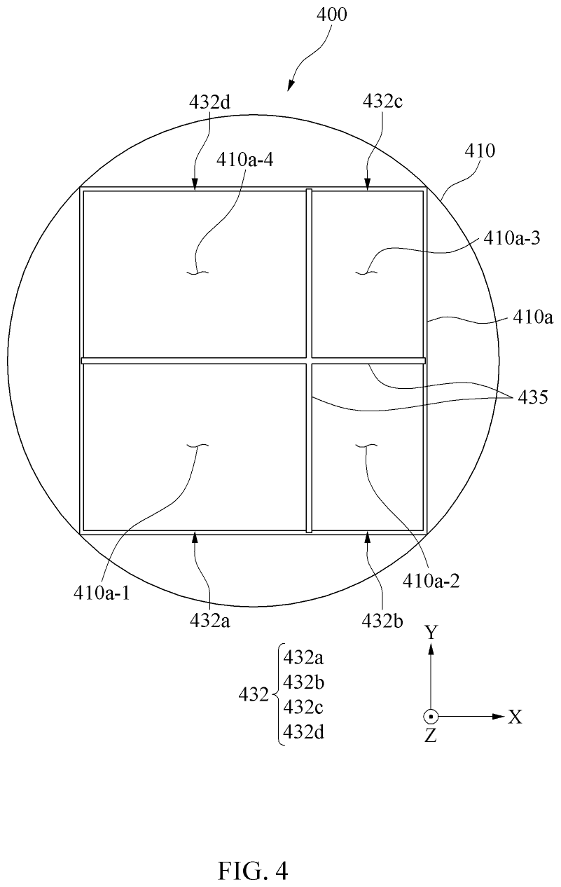

FIG. 4 is a plan view illustrating sizes of a plurality of sections 410a-1, 410a-2, 410a-3, and 410a-4 formed in a semiconductor apparatus 400, according to an embodiment.

Referring to FIG. 4, the semiconductor apparatus 400 (e.g., the semiconductor apparatus 200 of FIG. 2A) may include a semiconductor substrate 410 on which a plurality of semiconductor devices (e.g., the plurality of semiconductor devices 120 of FIG. 1) is mounted and a cooling device (e.g., the cooling device 130 of FIG. 1) provided on the semiconductor substrate 410 and configured to cool the semiconductor substrate 410. According to an embodiment, the cooling device may include a vapor chamber provided on the semiconductor substrate 410, a plurality of heat sinks 432 provided on the vapor chamber, and an inner wall 435 provided between the plurality of sections 410a-1, 410a-2, 410a-3, and 410a-4 of an active area 410a formed on the semiconductor substrate 410. The plurality of heat sinks 432 may include a first heat sink 432a, a second heat sink 432b, a third heat sink 432c, and a fourth heat sink 432d. In an embodiment, the plurality of heat sinks 432a, 432b, 432c, and 432d may be respectively provided to overlap the plurality of sections 410a-1, 410a-2, 410a-3, and 410a-4 of the active area 410a formed on the semiconductor substrate 410.

According to an embodiment, when the semiconductor substrate 410 is viewed from above (e.g., in the +Z-axis direction of FIG. 4), the sizes of at least two sections among the plurality of sections 410a-1, 410a-2, 410a-3, and 410a-4 of the active area 410a formed on the semiconductor substrate 410 may be the same or different. In an example case in which the sizes of at least two sections among the plurality of sections 410a-1, 410a-2, 410a-3, and 410a-4 of the active area 410a are different, the sizes of at least two heat sinks among the plurality of heat sinks 432a, 432b, 432c, and 432d may also be formed to be substantially the same as the sizes of the sections 410a-1, 410a-2, 410a-3, and 410a-4 that are different from each other. The plurality of heat sinks 432a, 432b, 432c, and 432d may independently cool the plurality of overlapping sections 410a-1, 410a-2, 410a-3, and 410a-4, respectively. The plurality of sections 410a-1, 410a-2, 410a-3, and 410a-4 of different sizes may be cooled to the same temperature or different temperatures.

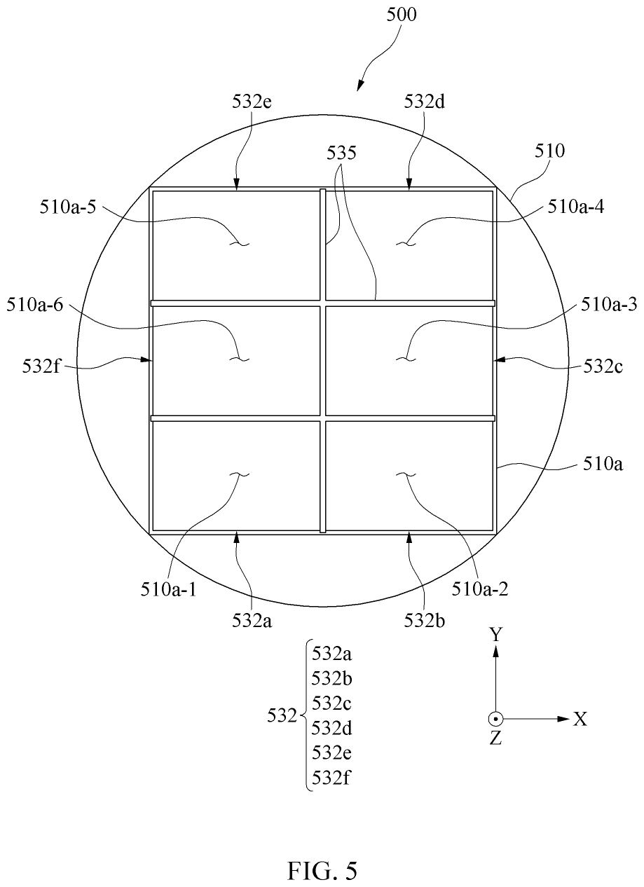

FIG. 5 is a plan view illustrating the number of sections 510a-1, 510a-2, 510a-3, 510a-4, 510a-5, and 510a-6 formed in a semiconductor apparatus 500, according to an embodiment.

Referring to FIG. 5, according to an embodiment, a semiconductor apparatus 500 (e.g., the semiconductor apparatus 100 of FIG. 1) may include a semiconductor substrate 510 (e.g., the semiconductor substrate 110 of FIG. 1) on which a plurality of semiconductor devices (e.g., the plurality of semiconductor devices 120 of FIG. 1) is mounted and a cooling device (e.g., the cooling device 130 of FIG. 1) provided on the semiconductor substrate 510 and configured to cool the semiconductor substrate 510. According to an embodiment, the cooling device may include a vapor chamber (e.g., the vapor chamber 231 of FIG. 2B) provided on the semiconductor substrate 510, a plurality of heat sinks 532 (e.g., the plurality of heat sinks 232 of FIG. 2B) provided on the vapor chamber, and an inner wall 535 (e.g., the inner wall 235 of FIG. 2A) provided between a plurality of sections 510a-1, 510a-2, 510a-3, 510a-4, 510a-5, and 510a-6 (e.g., the plurality of sections 210a-1, 210a-2, 210a-3, and 210a-4) of an active area 510a (e.g., the active area 210a of FIG. 2A) formed on the semiconductor substrate 510. A plurality of heat sinks 532 may be respectively provided to overlap the plurality of sections 510a-1, 510a-2, 510a-3, 510a-4, 510a-5, and 510a-6 of the active area 510a formed on the semiconductor substrate 510. For example, the plurality of heat sinks 532 may include a first heat sink 532a, a second heat sink 532b, a third heat sink 532c, a fourth heat sink 532d, a fifth heat sink 532e, and a sixth heat sink 532f. The plurality of heat sinks 532a, 532b, 532c, 532d, 532e, and 532f may respectively cool the plurality of sections 510a-1, 510a-2, 510a-3, 510a-4, 510a-5, and 510a-6 that is provided to respectively overlap the plurality of heat sinks 532a, 532b, 532c, 532d, 532e, and 532f through a coolant flowing in the plurality of heat sinks 532a, 532b, 532c, 532d, 532e, and 532f.

In an embodiment, a number of sections 510a-1, 510a-2, 510a-3, 510a-4, 510a-5, and 510a-6 of the active area 510a formed on the semiconductor substrate 510 may be at least two. For example, the number of sections (e.g., 510a-1, 510a-2, 510a-3, 510a-4, 510a-5, and 510a-6) of the active area 510a may be two, three, four, or more. Referring to FIG. 5, the active area 510a may include six sections 510a-1, 510a-2, 510a-3, 510a-4, 510a-5, and 510a-6. The plurality of heat sinks 532 may be provided in a quantity equal to the number of sections (e.g., 510a-1, 510a-2, 510a-3, 510a-4, 510a-5, and 510a-6) of the active area 510a. In an embodiment, the six heat sinks 532a, 532b, 532c, 532d, 532e, and 532f may be respectively provided to overlap the six sections 510a-1, 510a-2, 510a-3, 510a-4, 510a-5, and 510a-6. However, the number of sections (e.g., 510a-1, 510a-2, 510a-3, 510a-4, 510a-5, and 510a-6) of the active area 510a and the number of heat sinks 532 are both illustrated as six as only an example, and the number of sections (e.g., 510a-1, 510a-2, 510a-3, 510a-4, 510a-5, and 510a-6) of the active area 510a and the number of heat sinks 532 may vary (e.g., 2, 3, 4, 5, 7, 8 or more), and the number of sections (e.g., 510a-1, 510a-2, 510a-3, 510a-4, 510a-5, and 510a-6) of the active area 510a may be different from the number of heat sinks 532. For example, one heat sink 532 may be provided to overlap two sections (e.g., 510a-1, 510a-2, 510a-3, 510a-4, 510a-5, and 510a-6).

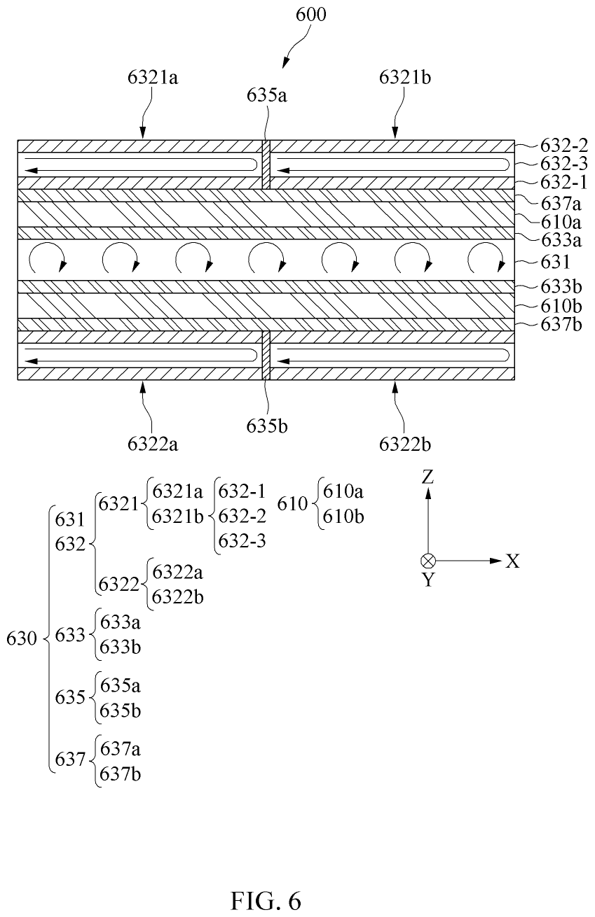

FIG. 6 is a cross-sectional view of a semiconductor apparatus 600 in which a vapor chamber 631 is provided between a plurality of semiconductor substrates 610, according to an embodiment.

Referring to FIG. 6, according to an embodiment, the semiconductor apparatus 600 (e.g., the semiconductor apparatus 100 of FIG. 1) may include a semiconductor substrate 610 (e.g., the semiconductor substrate 110 of FIG. 1) on which a plurality of semiconductor devices (e.g., the plurality of semiconductor devices 120 of FIG. 1) is mounted and a cooling device 630 (e.g., the cooling device 130 of FIG. 1) provided on the semiconductor substrate 610 and configured to cool the semiconductor substrate 610. According to an embodiment, the cooling device 630 may include a vapor chamber 631 (e.g., the vapor chamber 231 of FIG. 2B) provided on the semiconductor substrate 610, a plurality of heat sinks 632 (e.g., the plurality of heat sinks 232 of FIG. 2B) provided on the vapor chamber 631, a first TIM 633 (e.g., the first TIM 233 of FIG. 2B) provided between the vapor chamber 631 and the semiconductor substrate 610 and formed of a heat-conductive material, a second TIM 637 provided between the semiconductor substrate 610 and the plurality of heat sinks 632 and formed of a heat-conductive material, and an inner wall 635 provided between a plurality of sections (e.g., the plurality of sections 210a-1, 210a-2, 210a-3, and 210a-4) of an active area (e.g., the active area 210a of FIG. 2A) formed on the semiconductor substrate 610. The plurality of heat sinks 632 may include a first heat sink 6321a, a second heat sink 6321b, a third heat sink 6322a, and a fourth heat sink 6322b respectively provided to overlap the plurality of sections of the active area formed on the semiconductor substrate 610. The plurality of heat sinks 6321a, 6321b, 6322a, and 6322b may respectively cool the plurality of sections provided to overlap the plurality of heat sinks 6321a, 6321b, 6322a, and 6322b, respectively, through a coolant flowing in the plurality of heat sinks 6321a, 6321b, 6322a, and 6322b. Each of the plurality of heat sinks 6321a, 6321b, 6322a, and 6322b may include a lower base 632-1 (e.g., the lower base 232-1 of FIG. 2B), an upper base 632-2 (e.g., the upper base 232-2 of FIG. 2B), and a cooling channel 632-3 (e.g., the cooling channel 232-3 of FIG. 2B) through which a coolant flows.

In an embodiment, a plurality of semiconductor substrates 610 may be provided. The plurality of semiconductor substrates 610 may include an upper semiconductor substrate 610a and a lower semiconductor substrate 610b provided on the bottom (e.g., in the −Z-axis direction of FIG. 6) of the upper semiconductor substrate 610a. A plurality of semiconductor devices may be mounted on each of the upper semiconductor substrate 610a and the lower semiconductor substrate 610b.

In an embodiment, the vapor chamber 631 may be provided between the upper semiconductor substrate 610a and the lower semiconductor substrate 610b. The vapor chamber 631 may disperse heat generated by each of the upper semiconductor substrate 610a and the lower semiconductor substrate 610b through a phase change in a fluid flowing in the inner space of the vapor chamber 631. The vapor chamber 631 may disperse heat from both the upper semiconductor substrate 610a and the lower semiconductor substrate 610b, so with this structure, the size of the space required to cool one semiconductor substrate 610 may be reduced, and mountability may be improved.

In an embodiment, the plurality of heat sinks 632 may include an upper heat sink 6321 and a lower heat sink 6322. The upper heat sink 6321 may be provided on the upper semiconductor substrate 610a. The lower heat sink 6322 may be provided on the bottom of the lower semiconductor substrate 610b. The upper heat sink 6321 and the lower heat sink 6322 may be positioned to face each other with the vapor chamber 631 interposed therebetween. The upper heat sink 6321 may include the first heat sink 6321a and the second heat sink 6321b, and the lower heat sink 6322 may include the third heat sink 6322a, and the fourth heat sink 6322b.

In an embodiment, the first TIM 633 may include a first first TIM 633a, provided between the vapor chamber 631 and the upper semiconductor substrate 610a, and may include a second first TIM 633b, provided between the vapor chamber 631 and the lower semiconductor substrate 610b. The first first TIM 633a and the second first TIM 633b may transfer heat generated from the upper semiconductor substrate 610a and the lower semiconductor substrate 610b to the vapor chamber 631. In an embodiment, the third TIM 637, 637a, 637b may be provided between the semiconductor substrate 610 and the plurality of heat sinks 632. The second TIM 637 may include a first second TIM 637a configured to transfer heat generated from the upper semiconductor substrate 610a to the heat sink 632 and a second second TIM 637b configured to transfer heat generated from the lower semiconductor substrate 610b to the heat sink 632. For example, the first second TIM 637a may be provided between the upper semiconductor substrate 610a and the upper heat sink 6321, and the second second TIM 637b may be provided between the lower semiconductor substrate 610b and the lower heat sink 6322.

In an embodiment, an inner wall 635 may be provided between a plurality of sections of the active area on the semiconductor substrate 610. For example, the inner wall 635 may include a plurality of inner walls 635a, 635b. For example, a first inner wall 635a of the plurality of inner walls 635 may be provided between the plurality of sections of the active area of the upper semiconductor substrate 610a, and a second inner wall 635b of the plurality of inner walls 635 may be provided between the plurality of sections of the active area of the lower semiconductor substrate 610b.

FIG. 7 is a diagram schematically illustrating a semiconductor system 70 according to an embodiment.

Referring to FIG. 7, according to an embodiment, the semiconductor system 70 may include a semiconductor apparatus 700 (e.g., the semiconductor apparatus 100 of FIG. 1), a coolant supply device 701 connected to the semiconductor apparatus 700, a sensor device 702, and a control device 703. However, the disclosure is not limited thereto, and as such, according to another embodiment, the semiconductor system 70 may include one or more other components. According to an embodiment, the semiconductor apparatus 700 may include a semiconductor substrate (e.g., the semiconductor substrate 110 of FIG. 1) on which a plurality of semiconductor devices (e.g., the plurality of semiconductor devices 120 of FIG. 1) is mounted and a cooling device (e.g., the cooling device 130 of FIG. 1) provided on the semiconductor substrate and configured to cool the semiconductor substrate.

In an embodiment, the sensor device 702 may be connected to a semiconductor substrate of the semiconductor apparatus 700. The sensor device 702 may monitor the temperature of each of a plurality of sections (e.g., the plurality of sections 210a-1, 210a-2, 210a-3, and 210a-4 of FIG. 2A) of an active area (e.g., the active area 210a of FIG. 2A) formed on the semiconductor substrate. For example, the sensor device 702 may differentiate between each of the plurality of sections and obtain separate temperature information for each of the plurality of sections. The sensor device 702 may include a temperature sensor. The sensor device 702 may include various sensors (e.g., a power sensor, a humidity sensor, and a position sensor) that may detect various states (e.g., power consumption, humidity, and position) of each of the plurality of sections of the active area, in addition to the temperature sensor.

In an embodiment, the coolant supply device 701 may supply a coolant to a plurality of heat sinks (e.g., the plurality of heat sinks 232 of FIG. 2B) of the cooling device (e.g., the cooling device 230 of FIG. 2B). The coolant supply device 701 may be connected to the plurality of heat sinks. For example, the coolant supply device 701 may be connected to an inlet (e.g., the inlets 232-4a and 232-4b of FIGS. 2C and 2D) of each of the plurality of heat sinks. The coolant supply device 701 may include a pumping device for introducing a coolant into the inlet of each of the plurality of heat sinks 232.

In an embodiment, the control device 703 may control an output of the coolant supply device 701, based on the temperature result of each section of the active area monitored by the sensor device 702. The control device 703 may be connected to the sensor device 702 and the coolant supply device 701. In an embodiment, the control device 703 may include various devices (e.g., an actuator and a power supply) for controlling the output of the coolant supply device 701. The control device 703 may include a processor or controller for controlling an output. The control device 703 may control the output of the coolant supply device 701 when the temperature of a section monitored by the sensor device 702 is not within a reference range. The reference range may be a predetermined range. For example, the control device 703 may control the output of the coolant supply device 701 based on a determination that the temperature of a section monitored by the sensor device 702 outside the reference range. For example, in a case in which the temperature of the monitored section is higher than a an upper end of the reference range, the control device 703 may increase the output of the coolant supply device 701 to increase the amount of the coolant supplied to a heat sink. In an example case in which the temperature of the monitored section is less than a lower end of the reference range, the control device 703 may reduce the output of the coolant supply device 701 to reduce the amount of the coolant supplied to the heat sink.

Although the embodiments have been described with reference to the limited drawings, one of ordinary skill in the art may apply various technical modifications and variations based thereon. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and/or equivalents of the claims are within the scope of the following claims.

What is claimed is:

1. A semiconductor apparatus comprising:
a semiconductor substrate comprising an active area that is divided into a plurality of sections in which a plurality of semiconductor devices are provided; and
a cooling device comprising: a vapor chamber configured to disperse heat generated by the plurality of sections through a phase change in a fluid flowing inside the vapor chamber; and
a plurality of heat sinks configured to respectively cool corresponding sections of the plurality of sections through a coolant flowing inside the plurality of heat sinks.

2. The semiconductor apparatus of claim 1, wherein
the vapor chamber is provided on the semiconductor substrate, and
the plurality of heat sinks are provided on the vapor chamber.

3. The semiconductor apparatus of claim 1, wherein
the vapor chamber is provided on a first side of the semiconductor substrate, and
the plurality of heat sinks is provided on a second side of the semiconductor substrate.

4. The semiconductor apparatus of claim 1, wherein each of the plurality of heat sinks comprises:
a first base;
a second base; and
a channel provided between the first base and the second base, the channel configured to enable the coolant to flow.

5. The semiconductor apparatus of claim 4, wherein,
the channel comprises:
a plurality of first passages extending in a first direction and provided side by side in a second direction substantially perpendicular to the first direction; and
a plurality of second passages configured to connect adjacent first passages, among the plurality of second passages, and
a width of each of the plurality of first passages is substantially same as a distance between the adjacent first passages.

6. The semiconductor apparatus of claim 4, wherein
each of the plurality of heat sinks is formed in a polygonal shape having a plurality of sides,
each of the plurality of heat sinks comprises:
an inlet configured to introduce the coolant into the channel, and
an outlet configured to discharge the coolant from the channel, and
the inlet and the outlet of at least one of the plurality of heat sinks are positioned on a same side of the at least one of the plurality of heat sinks.

7. The semiconductor apparatus of claim 4, wherein
each of the plurality of heat sinks is formed in a polygonal shape having a plurality of sides,
each of the plurality of heat sinks comprises:
an inlet configured to introduce the coolant into the channel, and
an outlet configured to discharge the coolant from the channel, and
the inlet and the outlet of at least one of the plurality of heat sinks are positioned on different sides of the at least one of the plurality of heat sinks.

8. The semiconductor apparatus of claim 1, wherein the cooling device further comprises a thermal interface material (TIM) provided between the semiconductor substrate and the vapor chamber.

9. The semiconductor apparatus of claim 1, wherein the cooling device further comprises a thermal interface material (TIM) provided between the vapor chamber and the plurality of heat sinks.

10. The semiconductor apparatus of claim 1, wherein the cooling device further comprises an inner wall provided between adjacent sections, among the plurality of sections.

11. The semiconductor apparatus of claim 10, wherein the cooling device further comprises an outer wall provided along a perimeter of the active area.

12. The semiconductor apparatus of claim 11, wherein at least one of the inner wall or the outer wall comprises at least one of stainless steel, aluminum, or a combination of stainless steel and aluminum.

13. The semiconductor apparatus of claim 1, wherein at least two of the plurality of sections have substantially a same size.

14. The semiconductor apparatus of claim 1, wherein at least two of the plurality of sections have different sizes.

15. The semiconductor apparatus of claim 1, wherein the semiconductor substrate has a scale of a wafer level system.

16. A semiconductor apparatus comprising:
a semiconductor substrate comprising an active area that is divided into a plurality of sections in which a plurality of semiconductor devices are provided; and
a cooling device comprising:
a vapor chamber configured to disperse heat generated by the plurality of sections through a phase change in a fluid flowing inside the vapor chamber; and
a plurality of heat sinks configured to respectively cool corresponding sections among the plurality of sections through a coolant flowing inside the plurality of heat sinks,
wherein an area of the active area is at least about 22,500 square millimeters (mm²).

17. The semiconductor apparatus of claim 16, wherein at least some of the plurality of semiconductor devices are connected to one another to form at least one chiplet.

18. The semiconductor apparatus of claim 17, wherein the at least one chiplet comprises an active element, a memory element, or a combination of an active element and a memory element.

19. A semiconductor system comprising:
a semiconductor apparatus comprising:
a semiconductor substrate at a wafer level system scale, the semiconductor substrate comprising an active area that is divided into a plurality of sections;
a plurality of semiconductor devices provided in the active area of the semiconductor substrate, and
a cooling device configured to cool the active area of the semiconductor substrate;
a coolant supply device configured to supply a coolant to the cooling device;
a sensor device configured to obtain temperature information for each of the plurality of sections; and
a control device configured to:
receive the temperature information from the sensor device; and
control the coolant supply device to supply of the coolant to independently adjust a temperature of each of the plurality of sections based on the temperature information obtained for each of the plurality of sections.

20. The semiconductor system of claim 19, wherein
the cooling device comprises:
a vapor chamber configured to disperse heat generated by the plurality of sections through a phase change in a fluid flowing inside the vapor chamber; and
a plurality of heat sinks configured to respectively cool corresponding sections among the plurality of sections through a coolant flowing inside the plurality of heat sinks, and
the coolant supply device is connected to the plurality of heat sinks and configured to supply the coolant to the plurality of heat sinks.
